(19) United States
(12) Patent Application Publication
(10) Pub. No.: US 2007/0115149 A1
(43) Pub. Date: May 24, 2007

(54) Systems and methods for managing data on a portable storage device

(75) Inventors: Johnathan P. Tann, San Francisco, CA (US); James P. Tann, Monterey, CA (US); Richard T. Culver, San Jose, CA (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(73) Assignee: Macroport, Inc.

(21) Appl. No.: 11/285,990

(22) Filed: Nov. 23, 2005

(51) Int. Cl. H03M 7/00

(52) U.S. Cl. 341/50

(57) ABSTRACT

The present invention is generally directed towards systems and methods for managing multimedia data on a portable storage device. In one embodiment, a computer program product includes a computer-usable medium having a sequence of instructions which, when executed by a processor of a computing device, causes said processor to execute a process for managing multimedia data on a portable storage device of a particular type when the memory card is communicatively coupled with the computing device. The process includes detecting when the portable storage device is communicatively coupled to the with the computing device, determining the particular type of portable storage device, searching the memory card for multimedia data, copying the multimedia data into one or more target directories in the computing device if multimedia data is found, searching the computing device for account information for a multimedia service provider, and uploading the multimedia data to the multimedia service provider if account information is found.

### FIELD OF THE INVENTION

The various embodiments disclosed herein relate to portable storage devices, and more particularly to improved systems and methods for managing data on a portable storage device.

### BACKGROUND OF THE INVENTION

The portable nonvolatile memory device, such as a universal serial bus (“USB”) drive, a Multi-Media Card (“MMC”) or a Compact Flash memory card, has replaced a significant portion of traditional multimedia storage, such as magnetic tape or film, as the portable storage device of choice for cameras, video cameras, and audio players. This is largely due to the amount of storage space available in an inexpensive device that is a fraction of the size of traditional magnetic disks and tapes. Moreover, nonvolatile memory is reusable. After a user fills up a memory card with data, the user can upload the data to another storage device, such as a hard drive of a personal computer or a server, and then empty the memory card for additional use without degrading the quality of the data.

One problem that typically arises with the use of portable memory devices is the management of the data. Uploading and organizing large amounts of multimedia data, such as pictures, audio, and video, into complicated directory trees on a personal computer or a web server can be unwieldy, particularly for users who are not as comfortable with navigating through a web server or personal computer. Accordingly, improved systems and methods for managing data on a portable storage device would be desirable.

### SUMMARY OF THE INVENTION

The various embodiments disclosed herein are generally directed towards systems and methods for managing multimedia data on a portable storage device. In one embodiment, a computer program product includes a computer-usable medium having a sequence of instructions which, when executed by a processor of a computing device, causes said processor to execute a process for managing multimedia data on a portable storage device of a particular type when the portable storage device is communicatively coupled with the computing device. The process includes detecting when the portable storage device is communicatively coupled to the with the computing device, determining the particular type of portable storage device, searching the portable storage device for multimedia data, copying the multimedia data into one or more target directories in the computing device if multimedia data is found, searching the computing device for account information for a multimedia service provider, and uploading the multimedia data to the multimedia service provider if account information is found. If no account information is found, the process may prompt the user to create a new account to a particular multimedia service provider.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

In order to better appreciate how the above-recited and other advantages and objects of the present inventions disclosed herein are obtained, a more particular description of the present inventions briefly described above will be rendered by reference to specific embodiments thereof, which are illustrated in the accompanying drawings. Understanding that these drawings depict only typical embodiments of the invention and are not therefore to be considered limiting of its scope, the invention will be described and explained with additional specificity and detail through the use of the accompanying drawings in which:

FIG. 1 is an illustration of the operating environment for an embodiment of the present invention.

FIG. 2 is a diagram of an embodiment of the present invention.

FIG. 3 is a flowchart of a program in accordance with an embodiment of the present invention.

### DETAILED DESCRIPTION OF THE PREFERRED EMBODIMENTS

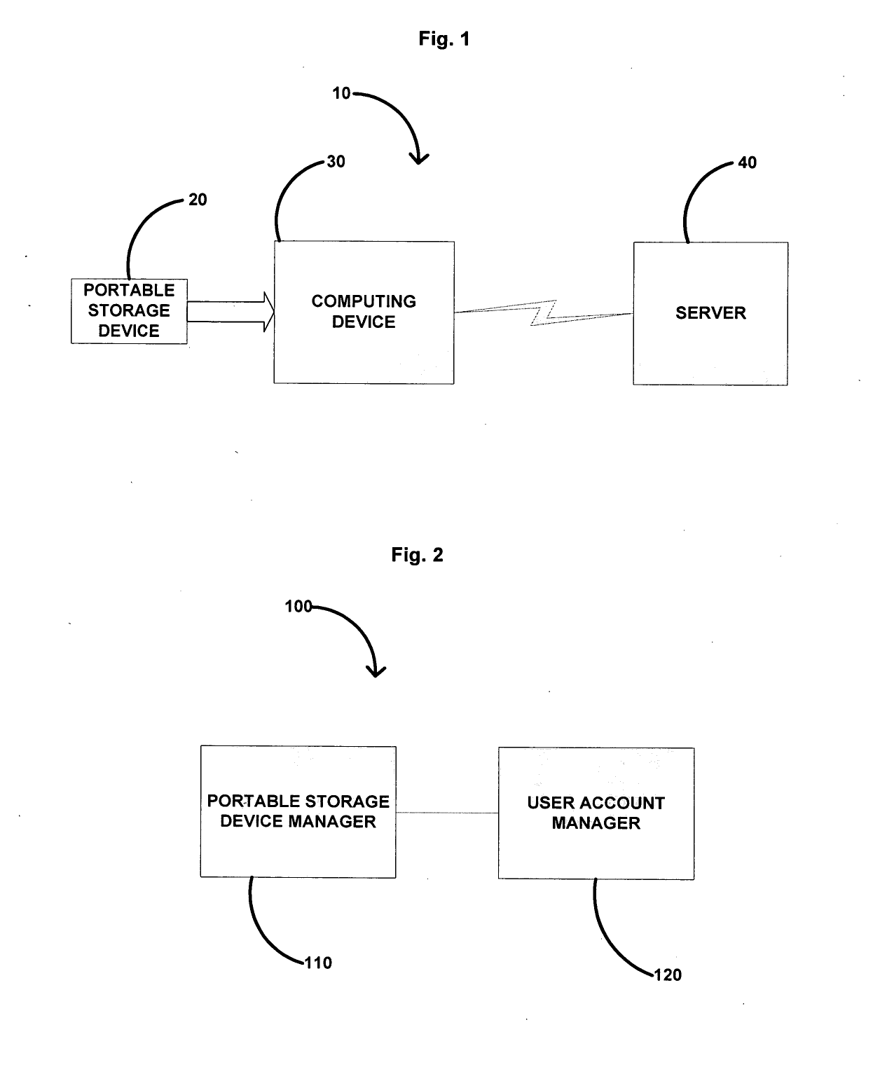

Turning to FIG. 1, the operating environment 10 for a preferred embodiment of the present invention is illustrated. The embodiments described below generally manage multimedia data stored on a portable storage device 20, such as a memory card. The multimedia data can include video, photos, and audio files. The multimedia data in the portable storage device 20 is generally captured or recorded by a multimedia recording device such as a camera, a video camera, mobile phone, or an audio recorder (not shown), and users typically transfer or upload the multimedia data from the portable storage device 20 to a computing device 30—a device with a processor and storage capabilities, such as a personal computer or a personal digital assistant, which is often relied upon by end users as a central storage device for all their multimedia data because of its comparably larger storage capacity and secure location. Subsequently, the user can then delete the data from the portable storage device 20 to create more storage space for additional data to be captured. In addition, or in the alternative, the multimedia data can be uploaded from the portable storage device 20 to a remote server 40, such as a web server over the Internet, via the computing device 30. Such a server 40 can be a simple storage server and/or a third party multimedia service provider, e.g., Kodak™ or SnapFish™, which generate prints from uploaded digital images, or servers that generate DVDs or CDs from uploaded multimedia data, such as digital videos, photos, and/or audio files.

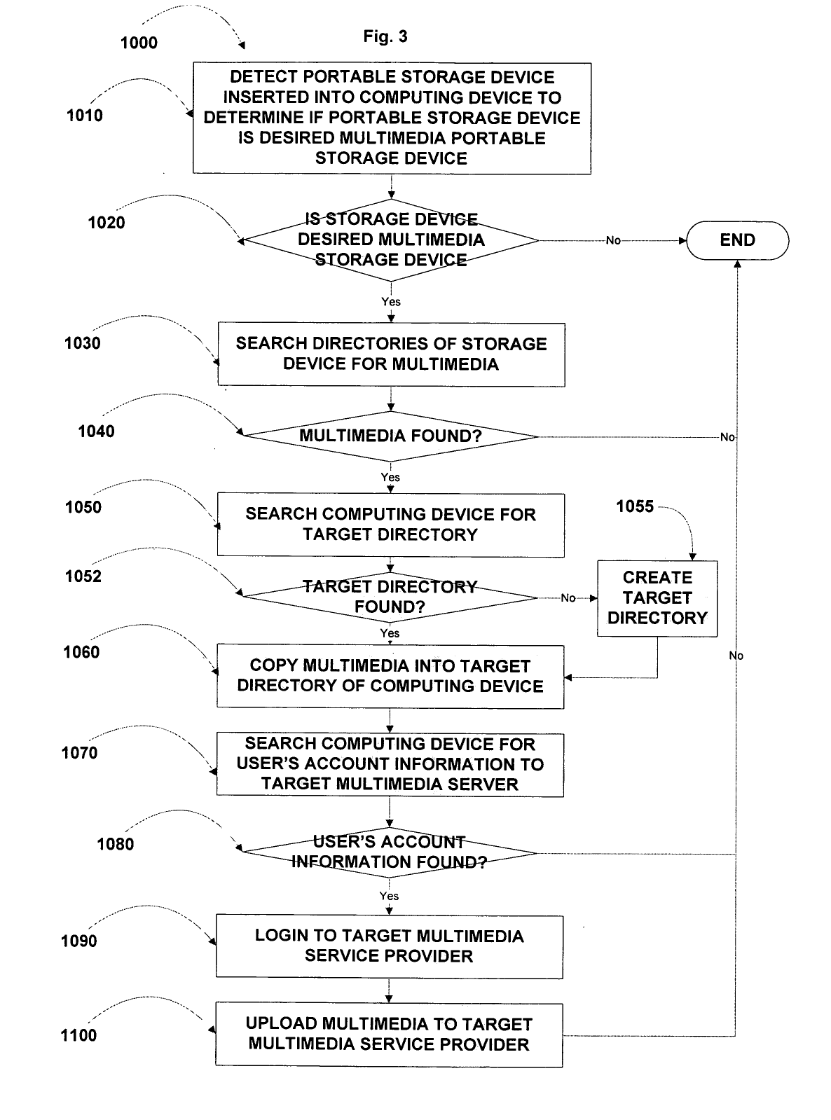

In accordance with one embodiment, a computer program 100, shown in FIG. 2, is installed in the computing device 30 that manages the multimedia data on the portable storage device 20. The computer program 100 generally includes a portable storage device manager 110 and a user account manager 120. The operation 1000 of the computer program 100 is illustrated in FIG. 3. The computer program 100 can be configured to run as a daemon program, which is a program that runs unattended “in the background” of the computing device to perform continuous or period functions. During operation, the computer program 100 detects when a portable storage device 20 has been inserted into the computing device 30. In the case where the computing device 30 is a personal computer with an operating system such as Microsoft Windows XP™, the operating system itself can detect the insertion of a portable storage device 20. The portable storage device manager 110 of the computer program 100, in such a case, can register with the operating system when the computing device 30 boots up, requesting that the operating system notify the portable storage device manager 110 if a portable storage device 20 has been inserted, or removed (action block 1010). When a portable storage device 20 has been inserted into the computing device 30, the portable storage device manager 110 will determine the type of portable storage device 20, e.g., Multi-Media Cards (“MMC”), Compact Flash Cards, USB drives, or Secure Digital cards (“SD”). Because different types of devices 20 can have different sizes, different device types may require different readers (not shown). The portable storage device manager 110 can detect the type of portable storage device 20 inserted into the personal computer and then detect the corresponding reader, which is particularly useful in the event the personal computer has more than one reader.

After the portable storage device 20 type is detected, the portable storage device manager 110 then searches the portable storage device 20 to determine if the portable storage device 20 contains multimedia data. This determination may be achieved by searching each directory and subdirectory within the card 20 for particular file extensions that identified desired multimedia data, such as .JPG, TIFF, MPG, .WMV, .MOV, .MP3, .MP4, .ACC, or .WAV. In the alternative, or in addition, the portable storage device manager 110 can search for a particular key file within the card 20. The key file can contain information about which multimedia data to search for within the card 20. If this key file exists (decision block 1020), then the portable storage device manager 110 will search all the directories and subdirectories for the multimedia data type(s) specified in the key file. In one embodiment, a routine is employed by the portable storage device manager 110 that recursively searches the subdirectories in directories. In other words, upon completion of searching one directory, the routine will call upon itself if another subdirectory within the current directory is found, and will continue to do so until all nested subdirectories have been searched for the specified data (action block 1030).

In an alternative embodiment, the key file may be hidden to the user and the computer program 100 can be configured to operate only upon finding the hidden key file. Thus, the computer program 100 will only operate when a portable storage device 20 includes the hidden key file.

If the specified data is found (decision block 1040), then the portable storage device manager 110 will search the computing device 30 for one or more target directories and/or subdirectories where the specified data is to be copied (action block 1050). If the one or more target directories and/or subdirectories are found (decision block 1052), then the specified multimedia data in the portable storage device 20 is copied into the one or more target directories and/or subdirectories of the computing device 30 (action block 1060). The portable storage device manager 110 can also be configured to check if the one or more target directories and/or subdirectories already include one or more files of the multimedia data to be copied. If so, then the one or more files can be ignored.

If the one or more target directories and/or subdirectories do not exist in the computing device 30 (decision block 1052), then the portable storage device manager 110 creates the one or more target directories and/or subdirectories in the computing device 30 (action block 1055) and copies the multimedia data into the one or more target directories and/or subdirectories (action block 1060). The one or more target directories and/or subdirectories can be established based on the application utilized by the user to present or display the multimedia data. For example, a third party digital photo application will typically create or rely on a particular default directory to store photos. In the case of a personal computer with an operating system such as Windows XP™, there is a directory created by the operating system called “My Pictures.” In one approach, if the one or more target directories and/or subdirectories do not exist and no multimedia applications exist, then the portable storage device manager 110 will create a subdirectory within the “My Pictures” directory based on the current data and then copy the multimedia data from the portable storage device 20 in the subdirectory.

In the alternative, or in addition to, copying the multimedia data from the portable storage device 20 to the personal computing device 30, the computer program 100 can also copy the data to a remote server and/or a third party multimedia service provider for presentation and additional data processing, such as Kodak™ or SnapFish™, as described above. The computer program 100 can search the computing device 30 for information about the remote server and/or web server, such as user account information (action block 1070) via the user account manager 120. In the case of an operating system such as Windows XP™, user account information can be stored in a cookie created in one of the subdirectories. If no cookie is found, the computer program 100 either aborts or gives the user the opportunity to create a user account at a particular website. The user account information can also be stored in the operating system registry.

If user account information for a multimedia service provider is found (decision block 1080), then the user account manager 120 will log in to the multimedia service provider using the user account information (action block 1090) and upload the multimedia data from the portable storage device 20 to the multimedia service provider's website (action block 1100). The computer program 100 will then “handoff” control to the user enabling the user to deal directly with the multimedia service provider.

The computer program 100 can further be user or account specific. In other words, data, such as a key file, within the portable storage device 20 can identify a specific account, which causes the computer program 100 to copy files to one or more target directories specific to the account and upload files to a multimedia service provider using the specific account. Each account can have different target directories and/or multimedia server providers associated with it. Thus, a portable storage device can be tied to or locked to one account.

As one of ordinary skill in the art will appreciate, the computer program 100 described above enables a novice user to manage multimedia data with a personal computing device 30 and/or a third party multimedia service provider without the need to manage the complicated directories and subdirectories of the personal computing device and/or remote server. All the user needs to do is insert the portable storage device 20 into the computing device 30, and the multimedia data will be copied, uploaded, and stored at the desired locations.

The computer program 100 can be pre-loaded onto a portable storage device 20 with a setup routine that will load all of the components for the computer program 100 onto the computing device 30 when the portable storage device 20 is inserted into the computing device 30 for the first time. In the case of a personal computer with Windows XP™, an entry can be added to the registry that enables the loading and running of the computer program 100 at boot up time.

Although particular embodiments of the present inventions have been shown and described, it will be understood that it is not intended to limit the present inventions to the preferred embodiments, and it will be obvious to those skilled in the art that various changes and modifications may be made without departing from the spirit and scope of the present inventions. Thus, the present inventions are intended to cover alternatives, modifications, and equivalents, which may be included within the spirit and scope of the present inventions as defined by the claims.

What is claimed is:

1. A computer program product that includes a computer-usable medium having a sequence of instructions which, when executed by a processor of a computing device, causes said processor to execute a process for managing multimedia data on a portable storage device of a particular type when the portable storage device is communicatively coupled with the computing device, said process comprising:
detecting when the portable storage device is communicatively coupled with the computing device;
determining the particular type of portable storage device;
searching the portable storage device for multimedia data;
if multimedia data is found, copying the multimedia data into one or more target directories in the computing device;
searching the computing device for account information for a multimedia service provider;
if account information is found, uploading the multimedia data to the multimedia service provider; and
if no account information is found, create a new account for the multimedia service provider.

2. The computer program product of claim 1, wherein multimedia data includes one or more of videos, photos, and audio files.

3. The computer program product of claim 1, wherein the searching of the portable storage device for multimedia data includes recursively searching every directory and subdirectory within the memory card.

4. The computer program product of claim 1, wherein the process further comprises searching the computing device for the one or more target directories; and creating the one or more target directories within the computing device if the one or more target directories did not previously exist within the one or more target directories.

5. The computer program product of claim 1, wherein the portable storage device is a removable nonvolatile memory card.

6. The computer program product of claim 1, wherein the process further includes searching the portable storage device for a hidden key file, wherein the hidden key file specifies what multimedia data to search for within the portable storage device.

7. The computer program product of claim 6, wherein the computer program product ceases operation if the hidden key file is not found.

8. The computer program product of claim 6, wherein the hidden key file identifies the one or more target directories in the computing device.

9. The computer program product of claim 8, wherein different hidden key files identify different target directories in the computing device.

10. The computer program product of claim 1, wherein the computing device is a personal computer having an operating system, and wherein the computer program product begins operation upon the operating system booting up.

11. The computer program product of claim 1, wherein the multimedia data is digital photos and the multimedia service provider converts the digital photos into print form.

12. The computer program product of claim 1, wherein the process operates as a daemon program.

13. A computer program product that includes a computer-usable medium having a sequence of instructions which, when executed by a processor of a computing device, causes said processor to execute a process for managing multimedia data on a removable nonvolatile memory device of a particular type when the removable nonvolatile memory device is communicatively coupled with the computing device, said process comprising:
detecting when removable nonvolatile memory device is communicatively coupled with the computing device;
searching the removable nonvolatile memory device for multimedia data;
searching the computing device for account information for a multimedia service provider;
if account information is found, uploading the multimedia data to the multimedia service provider; and
if no account information is found, create a new account for the multimedia service provider.

14. The computer program product of claim 13, wherein multimedia data includes one or more of videos, photos, and audio files.

15. The computer program product of claim 13, wherein the searching of the removable nonvolatile memory device for multimedia data includes recursively searching every directory and subdirectory within the removable nonvolatile memory device.

16. The computer program product of claim 13, wherein the process further includes searching the portable storage device for a hidden key file, wherein the hidden key file specifies what multimedia data to search for within the portable storage device.

17. The computer program product of claim 13, wherein the process further includes searching the portable storage device for a hidden key file, wherein the computer program product ceases operation if the hidden key file is not found.

18. The computer program product of claim 13, wherein the computing device is a personal computer having an operating system, and wherein the computer program product begins operation upon the operating system booting up.

19. The computer program product of claim 13, wherein the multimedia data is digital photos and the multimedia service provider converts the digital photos into print form.

20. The computer program product of claim 13, wherein the process operates as a daemon program.
